(19) United States
(12) Patent Application Publication
(10) Pub. No.: US 2006/0139125 A1
(43) Pub. Date: Jun. 29, 2006

(54) Filter device

(76) Inventors: Shigeyuki Shiga-ken, Kyoto-fu (JP); Norio Taniguchi, Shiga-ken (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(21) Appl. No.: 10/545,036

(22) PCT Filed: Nov. 25, 2004
(86) PCT No.: PCT/JP04/17460

§ 371 Date: Aug. 11, 2005

(30) Foreign Application Priority Data
Dec. 1, 2003 (JP) 2003-401888

(51) Int. Cl. H03H 9/64

(52) U.S. Cl. 333/193

(57) ABSTRACT

In a communication system including a first bandpass filter having a relatively low passband or a second bandpass filter having a relatively high passband, a filter device is used as the first bandpass filter. Series-arm resonators are inserted in a series arm connecting an input terminal and an output terminal. Parallel-arm resonators are connected in parallel arms connecting the series arm and a reference potential. Inductances are connected in series with at least one of the parallel-arm resonators. The resonant frequency of a secondary resonance generated by insertion of the inductances is within or in the vicinity of the passband of the receiver or transmitter bandpass filter serving as a partner filter of the ladder filter.

### BACKGROUND OF THE INVENTION

1. Field of the Invention

The present invention relates to a filter device having a plurality of resonators connected so as to have a ladder circuit structure, such as, for example, a filter device used as a transmitter bandpass filter or a receiver bandpass filter in a communication system.

2. Description of the Related Art

In general, ladder filters having a plurality of connected surface acoustic wave resonators are widely used as receiver bandpass filters or transmitter bandpass filters of surface acoustic wave devices. For example, Japanese Unexamined Patent Application Publication No. 5-183380 (Patent Document 1) discloses a ladder filter having a plurality of one-terminal-pair surface acoustic wave resonators alternately provided in parallel arms and a series arm from the input side to the output side. In Patent Document 1, as shown in FIG. 24, a parallel-arm resonator P1 is inserted in a parallel arm, and a series-arm resonator S1 is inserted in a series arm. Although a one-stage circuit structure is shown in FIG. 24, Patent Document 1 discloses a ladder filter having a plurality of stages. In Patent Document 1, an inductance L connected between the parallel-arm resonator P1 and a reference potential provides wide bandwidth and high attenuation.

Japanese Unexamined Patent Application Publication No. 10-163808 (Patent Document 2) discloses another ladder filter in which reference potential terminals of at least two parallel-arm resonators are commonly connected. FIG. 25 shows the circuit structure of a ladder filter 100 shown in Patent Document 2. As shown in FIG. 25, series-arm resonators S11 to S13 are provided in a series arm extending between an input terminal 101 and an output terminal 102. A parallel-arm resonator P11 is provided in a parallel arm connecting a node between the series-arm resonators S11 and S12 and the reference potential, and a parallel-arm resonator P12 is provided in a parallel arm connecting a node between the series-arm resonators S12 and S13 and the reference potential. The reference-potential-side terminals of the parallel-arm resonators P11 and P12 are commonly connected.

In the ladder filter 100 shown in Patent Document 2, the parallel-arm resonators P11 and P12 are commonly connected, thus providing high attenuation in the high-frequency passband.

With the recent developments in communication devices such as portable telephones, higher performance has been demanded for bandpass filters used in such devices. For example, transmitter bandpass filters used for 2-GHz-band WCDMA branching filters must have an insertion loss of no greater than 1.5 dB in the passband and must have an attenuation of no less than 37 dB. In the WCDMA method, the transmission passband is from 1920-MHz to 1980 MHz with a wide frequency range.

The circuit structure described in Patent Document 2 provides high attenuation in the high-frequency passband. Although the circuit structure described in Patent Document 2 provides for high attenuation in the high-frequency passband, it is difficult to provide a wide pass-bandwidth as well. It is therefore difficult to provide a filter that has sufficient attenuation and that can operate over a wide frequency range, such as a transmitter bandpass filter used for a 2-GHz-band WCDMA branching filter.

In the ladder filter described in Patent Document 1, on the other hand, the inductance L connected in series with the parallel-arm resonator P1 provides wide bandwidth and high attenuation. However, the optimum inductance value of the inductance L is not specifically disclosed. Furthermore, in Patent Document 1, there is no disclosure of any structure for specifically improving the attenuation in the high-frequency passband.

### SUMMARY OF THE INVENTION

To overcome the problems described above, preferred embodiments of the present invention provide, in a communication system including a first bandpass filter having a relatively low passband frequency and a second bandpass filter having a relatively high passband frequency, a filter device used for the first bandpass filter, wherein the filter device has a ladder circuit structure having a plurality of connected resonators and achieves sufficient attenuation, in particular, sufficiently high attenuation in the high-frequency passband, with low loss and wide bandwidth.

According to a preferred embodiment of the present invention, in a communication system including a first bandpass filter having a relatively low passband frequency and a second bandpass filter having a relatively high passband frequency, a filter device defining the first bandpass filter is provided. The filter device has a ladder circuit structure, and includes at least one series-arm resonator inserted in a series arm connecting an input terminal and an output terminal, at least one parallel-arm resonator connected in at least one parallel arm connecting the series arm and a reference potential, and an inductance connected in series with the at least one parallel-arm resonator, wherein the inductance has an inductance value such that the frequency of a secondary resonance generated in the parallel-arm resonator by inserting the inductance is within or in the vicinity of the passband of the second bandpass filter defining a partner filter of the filter device.

In the filter device according to a preferred embodiment of the present invention, each of the series-arm resonator and the parallel-arm resonator is preferably a surface acoustic wave resonator.

In the filter device according to a preferred embodiment of the present invention, each of the parallel-arm resonator and the series-arm resonator defining the ladder filter is preferably a piezoelectric thin film resonator.

In the filter device according to a preferred embodiment of the present invention, the piezoelectric thin film resonator preferably includes a substrate having an opening portion or a recessed portion, a piezoelectric thin film disposed above the opening portion or the recessed portion, and an upper electrode and a lower electrode facing each other with the piezoelectric thin film therebetween, the upper electrode being disposed on an upper surface of the piezoelectric thin film and the lower electrode being disposed on a lower surface of the piezoelectric thin film.

Preferably, the filter device according to this preferred embodiment further includes a piezoelectric thin film support layer disposed between the substrate and the piezoelectric thin film so as to cover the opening portion or the recessed portion of the substrate.

The filter device according to this preferred embodiment preferably further includes a package in which the series-arm resonator and the parallel-arm resonator of the ladder filter are connected, wherein the inductor is an inductance element connected to the parallel-arm resonator outside the package.

The filter device according to this preferred embodiment preferably further includes a mounting substrate on which the package is mounted, wherein the inductor is an inductance element embedded in the mounting substrate.

The filter device according to this preferred embodiment preferably further includes a package in which the filter device is mounted, wherein the inductor is incorporated in the package.

In a filter device according to a preferred embodiment of the present invention, an inductance is connected in series with at least one parallel-arm resonator, and the frequency of a secondary resonance generated by inserting the inductance is within or in the vicinity of the passband of a second bandpass filter defining a partner filter of the filter device, thus achieving a wide bandwidth, sufficient out-of-band attenuation, and low insertion loss in the passband. Therefore, a filter device with wide bandwidth, low loss, and high attenuation is provided.

When the parallel-arm resonator and the series-arm resonator defining the filter device are surface acoustic wave resonators, a bandpass filter with wide bandwidth, low loss, and high attenuation is provided using a surface acoustic wave device according to a preferred embodiment of the present invention.

When the series-arm resonator and the parallel-arm resonator are piezoelectric thin film resonators, a first bandpass filter with wide bandwidth, low loss, and high attenuation is provided using piezoelectric thin film resonators according to a preferred embodiment of the present invention.

When each piezoelectric thin film resonator includes a substrate having an opening portion or a recessed portion, a piezoelectric thin film disposed above the opening portion or the recessed portion, an upper electrode defined on an upper surface of the piezoelectric thin film, and a lower electrode defined on a lower surface of the piezoelectric thin film, it is difficult to prevent vibration of the piezoelectric thin film above the opening portion or the recessed portion. Thus, resonance characteristics using vibration of the piezoelectric thin film are provided.

When the piezoelectric thin film support layer is defined so as to cover the opening portion or the recessed portion, a piezoelectric resonator with a lamination structure of the piezoelectric thin film overlying the piezoelectric thin film support layer is provided. Therefore, a piezoelectric thin film resonator is easily produced using a variety of piezoelectric thin films.

When the filter device according to this preferred embodiment of the present invention further includes a package in which the series-arm resonator and the parallel-arm resonator of the ladder filter are connected, and the inductor is an inductance element connected to the parallel-arm resonator outside the package, the inductance element may be connected outside the package. Therefore, it is only necessary to provide an inductance element having various inductance values suitable for characteristic requirements as a separate component to easily produce the filter device according to a preferred embodiment of the present invention.

When a mounting substrate on which the package is mounted is further provided and the inductor is an inductance element embedded in the mounting substrate outside the package, the inductance element can be produced at the same time as a circuit pattern defined on or in the mounting substrate. Therefore, the productivity is improved.

When a package in which the filter device is mounted is further provided and the inductor is incorporated in the package, an operation to connect the inductance outside the package is unnecessary. Moreover, the inductance incorporated in the package reduces the size of the filter device.

Other features, elements, steps, characteristics, and advantages of the present invention will become more apparent from the following description of preferred embodiments of the present invention with reference to the attached drawings.

### BRIEF DESCRIPTION OF THE DRAWINGS

FIG. 1 is a circuit diagram of a ladder circuit according to a preferred embodiment of the present invention.

FIG. 2 is a plan view schematically showing the structure of the ladder filter according to the preferred embodiment shown in FIG. 1.

FIG. 3 is a schematic bottom view of the ladder filter shown in FIG. 2.

FIGS. 4(a) and 4(b) are circuit diagrams showing modifications of the structure including parallel-arm resonators and an inductance connected to the parallel-arm resonators according to a preferred embodiment of the present invention.

FIG. 5 is an attenuation-frequency characteristic diagram of the filter including only the parallel-arm resonator and the filter in which the inductance having various inductance values is connected in series with the parallel-arm resonator according to a preferred embodiment of the present invention.

FIG. 6 is an impedance-frequency characteristic diagram of the filter including only the parallel-arm resonator and the filter in which the inductance having various inductance values is connected in series with the parallel-arm resonator according to a preferred embodiment of the present invention.

FIG. 7 is an attenuation-frequency characteristic diagram of a ladder filter according to a first preferred embodiment of the present invention.

FIG. 8 is an attenuation-frequency characteristic diagram of a ladder filter of a comparative example that is manufactured according to the structure described in Patent Document 2.

FIG. 9 is a diagram showing the relationship among the bandwidth and the attenuation of the ladder filter according to a preferred embodiment of the present invention and the inductance value of the inductance connected to the parallel-arm resonator.

FIG. 10 is a diagram showing the relationship between the bandwidth and the attenuation of the ladder filter of the comparative example manufactured according to the related art described in Patent Document 2 and the inductance value of the inductance connected to the parallel-arm resonator.

FIG. 11 is a diagram showing the difference in attenuation-frequency characteristic of the ladder filter between when lines between the parallel-arm resonators and the inductances cross each other and when the lines do not cross each other.

FIG. 12 is a schematic plan view of a modification of the ladder filter shown in FIG. 2.

FIG. 13 is a schematic plan view of another modification of the ladder filter shown in FIG. 2.

FIG. 14 is a front cross-sectional view of a piezoelectric thin film resonator used as each of a series-arm resonator and a parallel-arm resonator in a preferred embodiment of the present invention.

FIG. 15 is a front cross-sectional view of a piezoelectric thin film resonator used as each of a series-arm resonator and a parallel-arm resonator in a preferred embodiment of the present invention.

FIG. 16 is a schematic plan view to show the structure of a filter device according to a modification of a preferred embodiment of the present invention.

FIG. 17 is a front cross-sectional view of a filter device according to another modification of a preferred embodiment of the present invention.

FIG. 18 is a schematic plan view to show a filter device according to still another modification of a preferred embodiment of the present invention.

FIG. 19 is a schematic front cross-sectional view to show a filter device according to still another modification of a preferred embodiment of the present invention.

FIG. 20 is a front cross-sectional view of a filter device according to still another modification of a preferred embodiment of the present invention.

FIG. 21 is a front cross-sectional view of a filter device according to still another modification of a preferred embodiment of the present invention.

FIG. 22 is a front cross-sectional view of a filter device according to another modification of a preferred embodiment of the present invention.

FIG. 23 is a front cross-sectional view of a filter device according to another modification of a preferred embodiment of the present invention.

FIG. 24 is a circuit diagram to show a ladder filter of the related art.

FIG. 25 is a circuit diagram to show another ladder filter of the related art.

### DETAILED DESCRIPTION OF PREFERRED EMBODIMENTS

Preferred embodiments of the present invention will be described below with reference to the drawings.

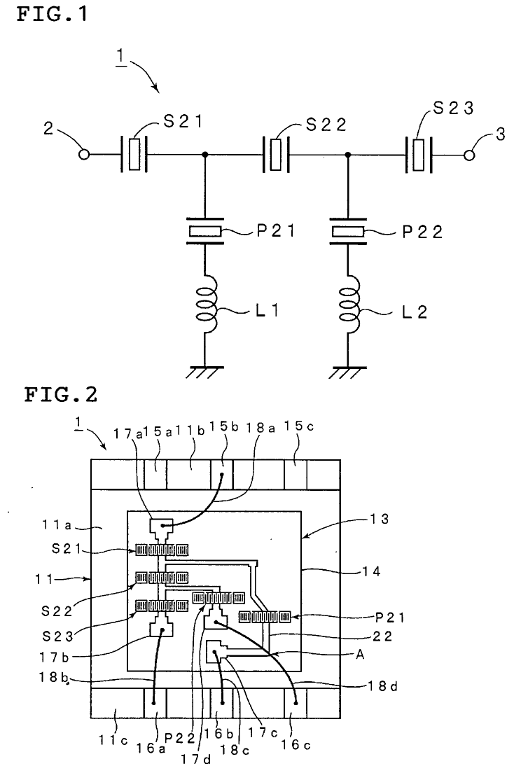

FIG. 1 is a circuit diagram of a ladder filter implemented as a filter device according to a preferred embodiment of the present invention. A ladder filter 1 according to the present preferred embodiment is preferably a transmitter bandpass filter used in a W-CDMA duplexer having a transmission band of about 1920 MHz to about 1980 MHz and a reception band of about 2110 MHz to about 2170 MHz. The transmission band is therefore lower than the reception band. That is, in a communication system including a first bandpass filter having relatively low frequency passband and a second bandpass filter having relatively high frequency passband, the ladder filter 1 is used as the first bandpass filter.

The ladder filter 1 includes a plurality of surface acoustic wave resonators that are connected so as to define a ladder circuit structure. That is, series-arm resonators S21, S22, and S23, each of which is a surface acoustic wave resonator, are provided in a series arm connecting an input terminal 2 and an output terminal 3. A parallel-arm resonator P21 is provided in a parallel arm extending between a node between the series-arm resonators S21 and S22 and a reference potential. An inductance L1 is connected in series with the parallel-arm resonator P21 between a reference-potential-side terminal of the parallel-arm resonator P21 and the reference potential. A parallel-arm resonator P22 is provided in a parallel arm between a node between the series-arm resonators S22 and S23 and the reference potential. An inductance L2 is connected between a reference-potential-side terminal of the parallel-arm resonator P22 and the reference potential.

In the ladder filter 1 according to the present preferred embodiment, therefore, the inductances L1 and L2 are connected in series with the parallel-arm resonators P21 and P22, respectively.

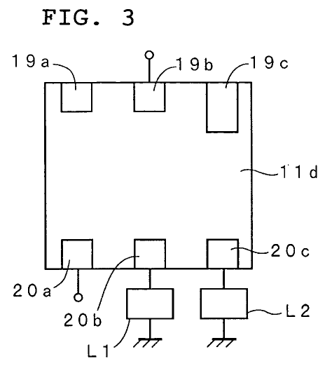

FIG. 2 is a schematic plan view showing the structure of the ladder filter according to the present preferred embodiment, and FIG. 3 is a schematic plan view of the ladder filter showing terminal electrodes disposed on the bottom surface thereof.

As shown in FIG. 2, the ladder filter 1 includes a package 11. In FIG. 2, a cover member for closing the package 11 is removed. That is, the package 11 has a recessed portion 11a, and a surface acoustic wave element 13 is received in the recessed portion 11a. The surface acoustic wave element 13 is configured preferably using substantially a rectangular piezoelectric substrate 14. An electrode pattern is provided on the piezoelectric substrate 14 such that the series-arm resonators S21 to S23 and the parallel-arm resonators P21 and P22 are electrically connected in the manner shown in FIG. 1. As shown in FIG. 2, each of the series-arm resonators S21 to S23 and the parallel-arm resonators P21 and P22 is a one-terminal-pair surface acoustic wave resonator including an interdigital electrode and reflectors disposed on both sides of the interdigital electrode in the surface wave propagation direction. On both sides of the recessed portion 11a of the package 11, step portions 11b and 11c which are arranged above the recessed portion 11a are provided. The step portions 11b and 11c include electrode lands 15a to 15c and 16a to 16c, respectively.

The piezoelectric substrate 14 includes electrode pads 17a to 17d. The electrode pad 17a is connected on the input port side of the series-arm resonator S21. Thus, the electrode pad 17a is an electrode pad provided at the input port side of the ladder filter 1. The electrode pad 17a is electrically connected to the electrode land 15b on the package 11 by a bonding wire 18a.

The electrode pad 17b is connected to an output port of the series-arm resonator S23. That is, this output port corresponds to an output port of the ladder filter 1. The electrode pad 17b is electrically connected to the electrode land 16a by a bonding wire 18b.

The electrode pad 17c is connected to the reference-potential-side terminal of the parallel-arm resonator P21. The electrode pad 17c is connected to the electrode land 16b by a bonding wire 18c. The electrode pad 17d is connected to the reference-potential-side terminal of the parallel-arm resonator P22, and is electrically connected to the electrode land 16c disposed on the package 11 by a bonding wire 18d.

In the present preferred embodiment, the piezoelectric substrate 13 is preferably a LiNbO₃ substrate. The interdigital electrodes, the reflectors, and the electrode pads are preferably made of a conducting material primarily containing Al.

In the present invention, however, the piezoelectric substrate material of the surface acoustic wave resonators and the conducting material of the electrodes are not limited to those described above.

In practice, the ladder filter 1 shown in FIG. 2 is covered by a cover member covering the recessed portion 11a of the package 11.

As shown in FIG. 3, the package 11 of the ladder filter 1 includes terminal electrodes 19a to 19c and 20a to 20c defined on a bottom surface 11d thereof. The terminal electrodes 19a to 19c are electrically connected to the electrode lands 15a to 15c, respectively, and the terminal electrodes 20a to 20c are electrically connected to the electrode lands 16a to 16c, respectively.

In the ladder filter 1 according to the present preferred embodiment, as shown in FIG. 3, the first and second inductances L1 and L2 are electrically connected outside the package 11 between the terminal electrodes 20b and 20c and the reference potential, respectively. That is, the inductances L1 and L2 shown in FIG. 1 are external inductance elements.

The package 11 is preferably made of alumina. However, the material of the package 11 is not limited to alumina, and may include other insulating ceramic, such as low temperature co-fired ceramic (LTCC), and other insulating materials, such as synthetic resin.

As shown in FIG. 2, a wiring pattern 22 that provides an electrical connection between the parallel-arm resonator P21 and the electrode pad 17c crosses the bonding wire 18d, as indicated by an arrow A.

In the present preferred embodiment, as described above, the inductances L1 and L2 are inductance elements provided outside the package 11. However, the inductances L1 and L2 may be incorporated in the package 11. That is, the inductances L1 and L2 may be incorporated in the package 11 by including a spiral inductor, a microstrip, or other suitable inductance component in the package 11 or by accommodating a chip-type inductance element in the package 11.

The ladder filter 1 according to the present preferred embodiment includes a feature that the frequency of a secondary resonance produced by the connection of the inductances L1 and L2 is set within the passband of the receiver bandpass filter defining a partner filter of the ladder filter 1, i.e., the frequency range of about 2110 MHz to about 2170 MHz, or is particularly set to an attenuation pole of the ladder filter 1, thus providing wide bandwidth, low loss, and high attenuation.

This feature will be described hereinafter.

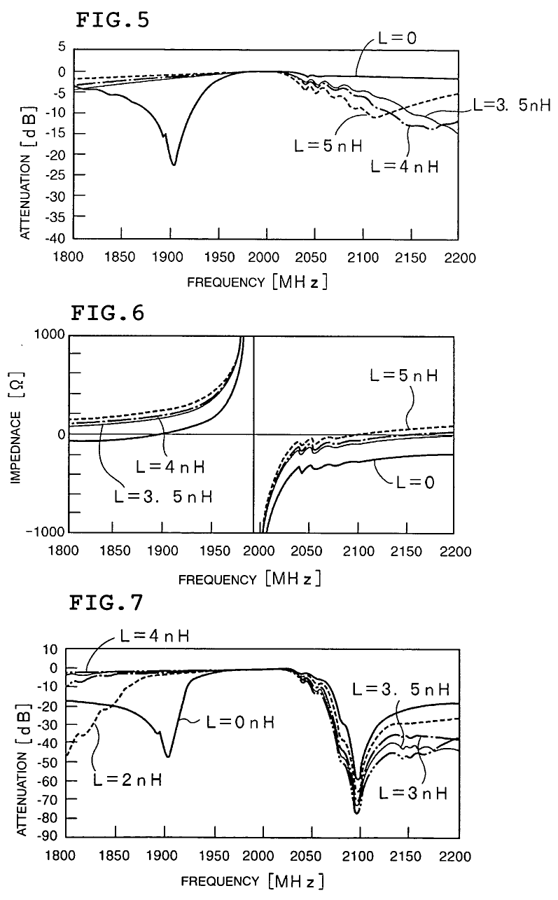

FIG. 5 is a transmission characteristic diagram of the ladder filter 1 including only the parallel-arm resonator P21 and the ladder filter 1 in which the inductance L1 having inductances of approximately 3.5 nH, 4 nH, and 5 nH is connected to the parallel-arm resonator P21. FIG. 6 is an impedance-frequency characteristic diagram of the ladder filter 1 including only the parallel-arm resonator P21 and the ladder filter 1 in which the inductance L1 having inductances of approximately 3.5 nH, 4 nH, and 5 nH is connected to the parallel-arm resonator P21.

The resonant frequency and the anti-resonant frequency of the parallel-arm resonator and the trap having the inductance connected to the parallel-arm resonator in the characteristic diagrams shown in FIGS. 5 and 6, and the frequency of the secondary resonance generated by the connection of the inductance are shown in Table 1 as follows:

Table 1

TABLE 1

| | | | secondary |
|---|---|---|---|
| | | anti-resonant | resonant |
| L | resonant frequency | frequency | frequency |
| [nH] | [MHz] | [MHz] | [MHz] |
| 0.0 | 1953 | 2044 | — |
| 3.5 | outside the range | 2044 | 2206 |
| | (1800 MHz or lower) | | |
| 4.0 | outside the range | 2044 | 2157 |
| | (1800 MHz or lower) | | |
| 5.0 | outside the range | 2044 | 2107 |
| | (1800 MHz or lower) | | |

In FIG. 6, the resonant frequency is a frequency at which the impedance crosses zero in a frequency region lower than the passband, the anti-resonant frequency is a frequency at which the absolute impedance value is the maximum in the passband, and the secondary resonant frequency is a frequency at which the impedance crosses zero in a frequency region higher than the passband.

In FIG. 5, attenuation poles are generated in frequency regions higher and lower than the passband. The frequencies at which the attenuation poles are generated are substantially equal to the first resonant frequency and the secondary resonant frequency shown in FIG. 6.

As shown in FIGS. 5 and 6, when the inductance L1 is connected, particularly when the inductance L1 has a higher inductance value, the frequency of the secondary resonance in a frequency region higher than the anti-resonant frequency of the parallel-arm resonator P21 is lower than when the inductance L1 is not connected. That is, the secondary resonance is used as a trap to thereby provide high attenuation in a high-frequency region of the ladder filter. Accordingly, in a preferred embodiment of the present invention, the secondary resonance generated by connecting the inductance L1 in series with the parallel-arm resonator P21 is used as a trap to thereby provide high attenuation in the frequency region higher than the passband.

FIG. 7 is an attenuation-frequency characteristic diagram of the ladder filter I when the inductance values of the inductances L1 and L2 are changed. As shown in FIG. 7, the ladder filter 1 including the inductances L1 and L2 having an inductance of about 3.5 nH or about 4 nH provides a wider pass-bandwidth and a higher attenuation in the frequency region higher than the passband, as compared to that in which the inductances L1 and L2 have an inductance of 0 nH, i.e., the inductances L1 and L2 are not connected.

In order to further explain this advantage, the ladder filter described in Patent Document 2 and the ladder filter according to the present preferred embodiment are compared.

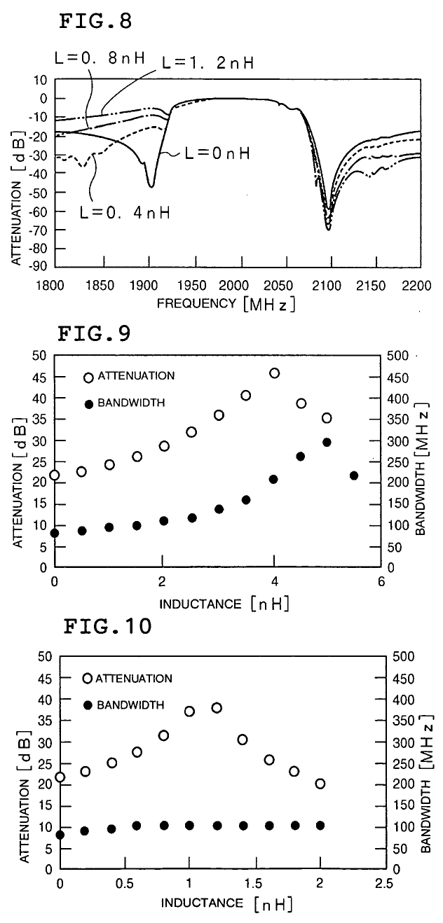

FIG. 8 is an attenuation-frequency characteristic diagram of a ladder filter provided in a comparative example. The comparative example provides a ladder filter manufactured in a similar manner to that according to the present preferred embodiment, except that the parallel-arm resonators in the ladder filter described in Patent Document 2, of which reference-potential-side terminals are commonly connected, are provided and inductances are connected between the reference-potential-side terminals and the reference potential, wherein the inductance values of the inductances are changed.

As is clear from the comparison between FIGS. 7 and 8, in the comparative example, attenuation poles exist in a frequency region lower than the passband, and the bandwidth does not increase even when the values of the inductances L1 and L2 are increased. In order to clearly show the difference between FIGS. 7 and 8, the relationship between the bandwidth and the attenuation of the ladder filter 1 according to the present preferred embodiment and the relationship between the bandwidth and the attenuation of the ladder filter of the comparative example are shown in graphs of FIGS. 9 and 10, respectively.

In FIGS. 9 and 10, the x-axis designates the inductance value of the connected inductances, wherein a white circle indicates the out-of-band attenuation (the minimum attenuation in the passband frequency range of about 2110 MHz to about 2170 MHz of the partner filter) and a black circle indicates the 3 dB bandwidth.

As shown in FIG. 10, in the ladder filter of the comparative example, the bandwidth does not increase even when the inductances are connected and the inductance values are changed. On the other hand, in the ladder filter 1 according to the present preferred embodiment, when the inductance values of the inductances L1 and L2 increase, the bandwidth increases, and the out-of-band attenuation also increases along with the increase of the inductance values, although the attenuation in the attenuation region decreases when the inductance values are too large.

It is therefore shown that the ladder filter of the comparative example does not achieve the effect of increasing the bandwidth even if an inductance is connected to parallel-arm resonators, whereas the ladder filter according to the present preferred embodiment provides a wide bandwidth and high attenuation. In addition, as shown in FIG. 9, the ladder filter 1 provides large out-of-band attenuation by selecting the inductance values. This results from the relationship between the secondary resonance generated in a region higher than the anti-resonant frequency by including the inductances L1 and L2 and the attenuation region. That is, as in the above-described preferred embodiment, the amount of increase of the attenuation is maximized when the secondary resonant frequency region is in the vicinity of the attenuation region of the ladder filter 1. The effect of increasing the bandwidth is also obtained, and a bandwidth about twice that in which the inductances L1 and L2 are not connected is achieved.

Thus, as in the above-described preferred embodiment, the frequency position of the secondary resonance produced by the connection of the inductances L1 and L2 is preferably at or in the vicinity of an attenuation pole of the ladder filter 1. In preferred embodiments of the present invention, as long as the secondary resonant frequency is within the passband of the receiver bandpass filter defining the partner bandpass filter of the ladder filter 1, high attenuation in the passband of the partner filter is achieved, and, as described above, wide bandwidth is also achieved. Furthermore, in the present preferred embodiment, as shown in FIG. 9, sufficient out-of-band attenuation and wide bandwidth are provided at inductances of about 3 nH to about 5 nH. As shown in Table 1, the secondary resonant frequency is about 2260 MHz with respect to an inductance of about 3 nH, and the secondary resonant frequency is about 2206 MHz with respect to an inductance of about 3.5 nH.

Therefore, although the effect of increasing the out-of-band attenuation is weaker than that in the above-described preferred embodiment, according to the present invention, the secondary resonant frequency position is set to be within or in the vicinity of the passband of the receiver bandpass filter defining the partner bandpass filter. The vicinity of the passband of the receiver bandpass filter defining the partner bandpass filter indicates a frequency position about 90 MHz higher than the passband of the partner filter because, as shown in FIG. 9, the attenuation is provided up to about 2260 MHz, which is the secondary resonant frequency with respect to an inductance of about 3 nH. Since the secondary resonant frequency also changes as the pass frequency of the filter changes, it can be seen that the secondary resonant frequency is set to the frequency position about 1.04 times the upper limit of the passband of the partner, wherein the secondary resonant frequency is normalized based on the upper limit of the passband of the partner filter to determine 2260/2170=about 1.04. Therefore, the vicinity of the passband of the receiver bandpass filter defining the partner bandpass filter is defined as a frequency band from the upper limit of the passband of the partner filter to the frequency position about 1.04 times the upper limit of the passband of the partner filter.

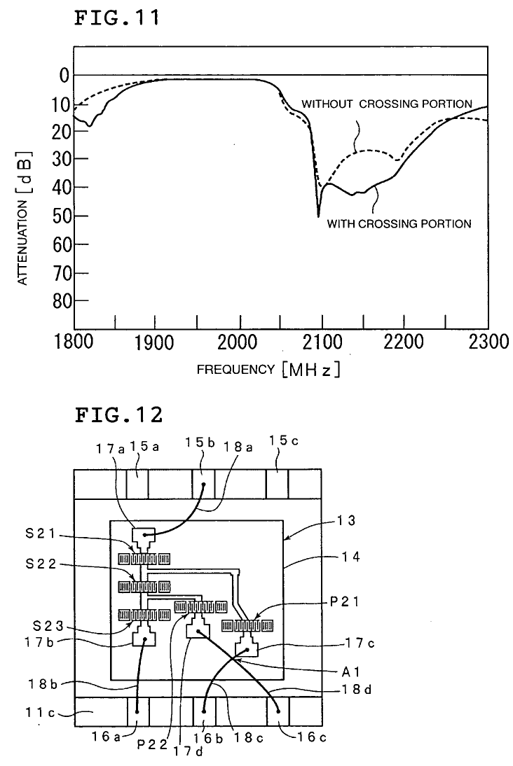

As shown in FIG. 2, in the ladder filter 1, the bonding wire 18d crosses the wiring pattern 22, as indicated by the arrow A. That is, an electrical line from the parallel-arm resonator P21 to the first inductance L1 and a line from the parallel-arm resonator P22 to the second inductance L2 cross each other. In the ladder filter 1, magnetic fluxes generated by both of these lines are cancelled out, and deterioration in attenuation is prevented when the inductances L1 and L2 are increased. Therefore, the crossing portion A enables higher attenuation. This will be described with reference to FIG. 11.

In FIG. 11, a solid line indicates the attenuation-frequency characteristic of the ladder filter 1 having the crossing portion A, and a broken line indicates the attenuation-frequency characteristic of a ladder filter produced in a similar manner to that in the above-described preferred embodiment, except that the bonding wire 18d is connected so as not to provide the crossing portion A. As is apparent from FIG. 11, the crossing portion A allows for high out-of-band attenuation.

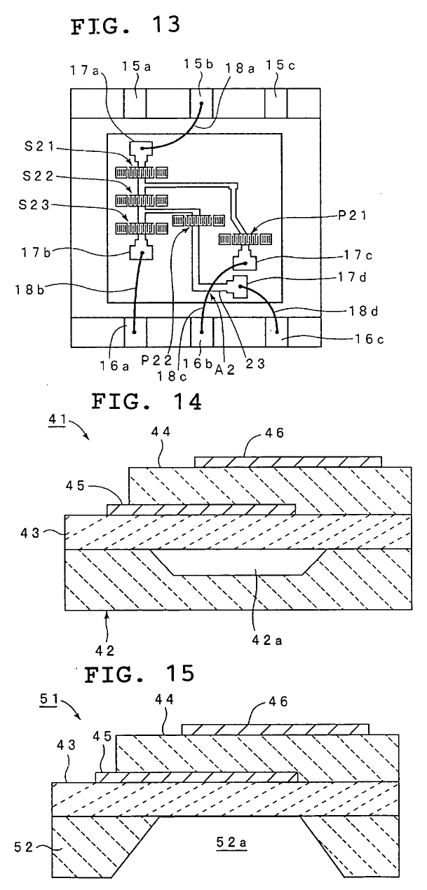

While the bonding wire 18d crosses the wiring pattern 22 in the manner indicated by the arrow A in the above-described preferred embodiment, the structure of the crossing portion may be modified, as shown in FIGS. 12 and 13. In a modification shown in FIG. 12, the bonding wire 18c connecting the electrode pad 17c and the electrode land 16b crosses the bonding wire 18d in the manner indicated by an arrow A1.

In the modification shown in FIG. 13, the bonding wire 18c crosses a wiring pattern 23 connecting the parallel-arm resonator P22 and the electrode pad 17d in the manner indicated by an arrow A2.

Accordingly, there are a variety of modifications of the structure in which a line between a first parallel-arm resonator and an inductance and a line between a second parallel-arm resonator and an inductance connected to the second parallel-arm resonator cross each other.

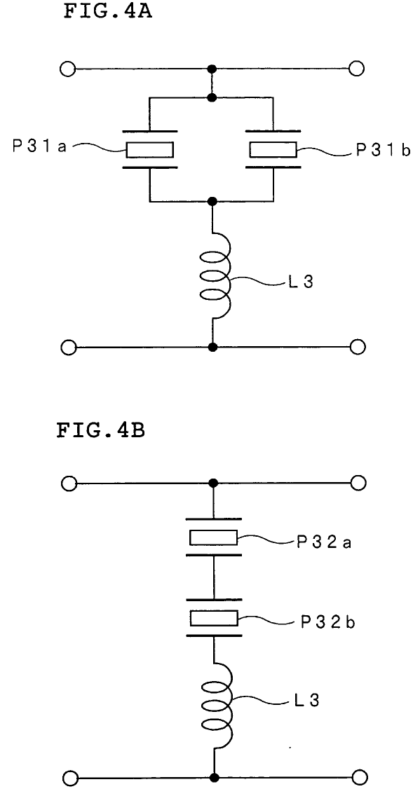

While inductance elements are connected in series with the parallel-arm resonators P21 and P22 between the parallel-arm resonators P21 and P22 and the reference potential in the present preferred embodiment, there are a variety of modifications of this structure. For example, as shown in FIG. 4(a), two resonators P31a and P31b connected in parallel to each other are provided in a single parallel arm, and an inductance L3 is connected between a reference-potential-side common node of the parallel-arm resonators P31a and P31b connected in parallel and a reference potential. Also, as shown in FIG. 4(b), in a single parallel arm, two parallel-arm resonators P32a and P32b are connected in series.

That is, parallel-arm resonators provided in a parallel arm may include a plurality of parallel-arm resonators connected in series or in parallel. In a single parallel arm, a plurality of inductance elements may also be connected in series or in parallel.

In addition, in a ladder filter having a plurality of stages, inductances are not necessarily connected in series with all parallel-arm resonators.

That is, an inductance should be connected in series with a reference-potential-side terminal of at least one of a plurality of parallel-arm resonators.

While the series-arm resonators S21 to S23 and the parallel-arm resonators P21 and P22 of the ladder filter 1 are surface acoustic wave resonators, they may be resonators other than surface acoustic wave resonators. The other resonators may include, for example, piezoelectric thin film resonators 41 and 51 shown in FIGS. 14 and 15.

The piezoelectric thin film resonator 41 shown in FIG. 14 includes a substrate 42 having a recessed portion 42a provided in the top surface thereof. A piezoelectric thin film support layer 43 is laminated so as to cover the recessed portion 42a. A piezoelectric thin film 44 is overlaid on the top surface of the piezoelectric thin film support layer 43. A lower electrode 45 is provided on a lower surface of the piezoelectric thin film 44, and an upper electrode 46 is provided on an upper surface thereof. The lower electrode 45 and the upper electrode 46 partially face each other with the piezoelectric thin film 44 therebetween, and the facing portion is provided above the recessed portion 42a of the substrate 42.

Thus, when an AC electric field is applied between the lower electrode 45 and the upper electrode 46, the portion at which the lower electrode 45 and the piezoelectric thin film 46 face each other is excited by the piezoelectric effect, and a resonance characteristic is obtained.

In the piezoelectric thin film resonator 41, the piezoelectric thin film 44 may be made of any suitable piezoelectric material, such as ZnO or AlN.

The lower electrode 45 and the upper electrode 46 may be made of any suitable conducting material, such as Al or Cu.

The substrate 42 may be made of any suitable insulating material or piezoelectric material as long as the substrate includes the recessed portion 42a. The materials of the substrate 42 may include, for example, alumina. The piezoelectric thin film support layer 43 covers the opening 42a and supports the piezoelectric thin film 44, and may be made of any suitable material which does not prevent vibration of the piezoelectric thin film 44. The piezoelectric thin film support layer 43 has a diaphragm structure, and is preferably configured so as to have a thickness that is sufficient so as not to prevent vibration of the piezoelectric thin film 44. The piezoelectric thin film support layer 43 may be made of, for example, SiO₂, Al₂O₃, or other suitable material.

The piezoelectric thin film resonator 51 shown in FIG. 15 includes a substrate 52 having an opening portion 52a. A lamination is formed over the opening portion 52a, including a piezoelectric thin film support layer 43, a lower electrode 45, a piezoelectric thin film 44, and an upper electrode 46. That is, the piezoelectric thin film resonator 51 has a similar structure to that of the piezoelectric thin film resonator 41, except that the substrate 52 including the opening 52a is provided in place of the substrate 42 including the recessed portion 42a shown in FIG. 14. Therefore, a piezoelectric thin film resonator may include the substrate 52 having the opening portion 52a perforated therein, as opposed to a top-open recessed portion. In this case, an exciting portion of the piezoelectric thin film 44 is located above the opening portion 52a.

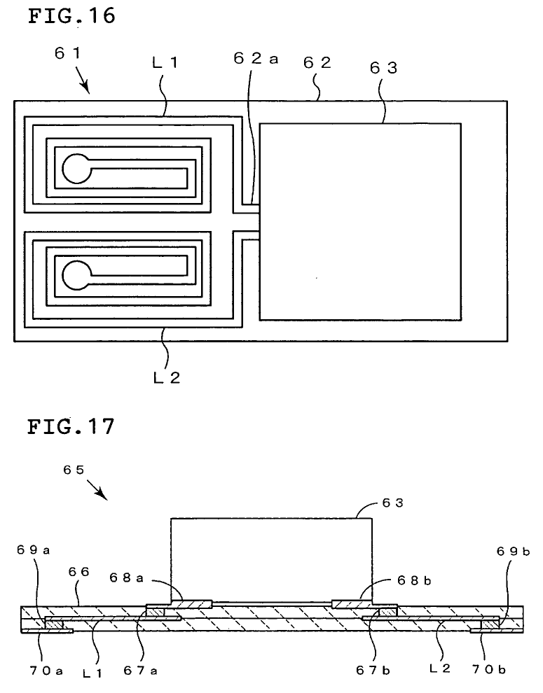

In the filter device according to a preferred embodiment of the present invention, the inductors may be arranged in a variety of configurations. FIGS. 16 and 17 are a schematic partial cutaway plan view and front cross-sectional view of a filter device according to modifications of preferred embodiments of the present invention, respectively. A filter device 61 according to the modification includes a mounting substrate 62. The mounting substrate 62 includes a package 63 mounted thereon. A ladder circuit including series-arm resonators and parallel-arm resonators defining the filter device according to the present invention as in the above-described preferred embodiment is provided in the package 63. That is, a piezoelectric substrate having a circuit structure excluding inductances connected in series with the parallel-arm resonators according to a preferred embodiment of the present invention is disposed in the package 63.

In the filter device 61, the inductances L1 and L2 connected in series with the parallel-arm resonators are coil-shaped conductor patterns on the top surface of the mounting substrate 62. Thus, the conductor patterns of the inductances L1 and L2 can be produced by the same process using the same material as that of a line 62a on the mounting substrate 62. Therefore, the inductances L1 and L2 can be formed without increasing the complexity of the manufacturing process. Since the inductances L1 and L2 are integrated on the mounting substrate 62, the number of components is reduced. The coil-shaped conductor patterns may be meander-shaped conductor patterns.

In a filter device 65 according to a modification shown in FIG. 17, which is a front cross-sectional view thereof, a mounting substrate 66 includes a package 63 mounted thereon. In this modification, conductor patterns of inductances L1 and L2 are provided in the mounting substrate 66. First ends of the inductances L1 and L2 having the conductor patterns are connected to wiring patterns 68a and 68b on the top surface of the mounting substrate 66 via via-hole electrodes 67a and 67b, respectively. The wiring patterns 68a and 68b are electrically connected to electrodes defined on the package 63. Second ends of the inductances L1 and L2 are electrically connected to terminal electrodes 70a and 70b on the bottom surface of the mounting substrate 66 by via-hole electrodes 69a and 69b provided in the mounting substrate 66, respectively. Alternatively, the connection by the via-hole electrodes 69a and 69b may be a connection by electrodes defined on side surfaces of the mounting substrate 66.

Also in the filter device 65 according to the present modification, the inductances L1 and L2 are embedded in the mounting substrate 66, to thus provide a filter device according to a preferred embodiment of the present invention without increasing the size thereof. The embedded inductances L1 and L2 can easily be produced according to a known manufacturing method, for example, a multilayer ceramic substrate. Therefore, the filter device 65 is provided without increasing the number of components and without increasing the number of manufacturing steps.

FIG. 18 is a schematic plan view showing a filter device according to another modification of a preferred embodiment of the present invention. In a filter device 71 shown in FIG. 18, a filter element 73 is disposed in a package 72. The filter element 73 has a similar structure to that of the filter element in the ladder filter 1 according to the first preferred embodiment. This modification includes coil-shaped conductor patterns provided on the top surface of the package 72 so as to define the inductances L1 and L2. Accordingly, the inductances L1 and L2 may be defined by providing conductor patterns on the top surface of the package 72. First ends of the inductances L1 and L2 are electrically connected to electrode lands on the filter element 73 via bonding wires 74a and 74b, respectively. Although not specifically shown, second ends of the inductances L1 and L2 are electrically connected, by via-hole electrodes (not shown), to terminal electrodes that are electrically connected to the outside. The coil-shaped conductor patterns may be meandering conductor patterns. The connection by the via-hole electrodes may be a connection by side-surface electrodes.

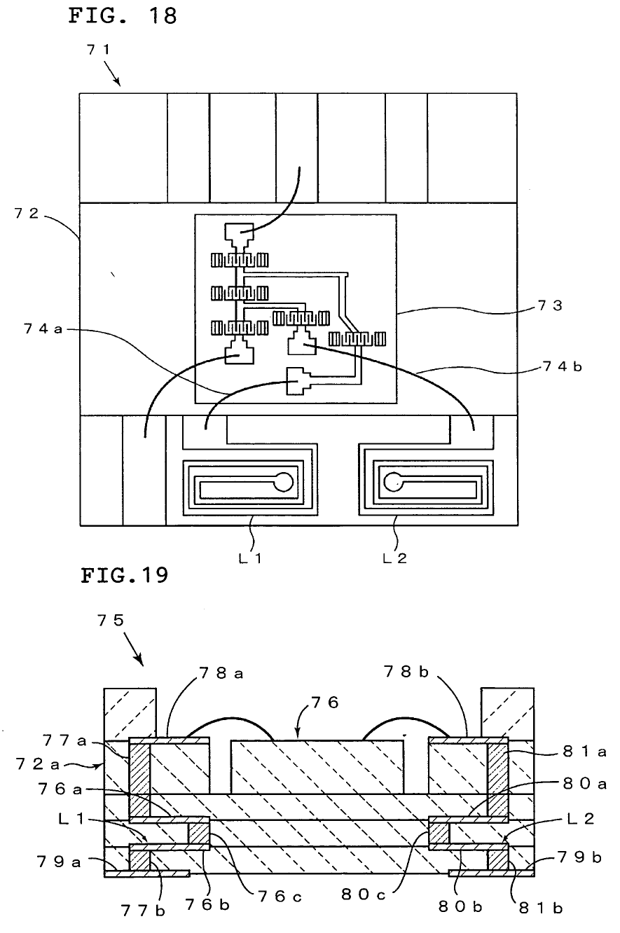

In a filter device 75 according to a modification shown in FIG. 19, a filter element 76 is disposed in a package 72a. The package 72a is a multilayer ceramic substrate. The package 72a includes inductances L1 and L2 incorporated therein. The inductances L1 and L2 are defined by coil patterns 76a and 76b formed at a plurality of heights in the package 72a and electrically connecting both coil patterns by a via-hole electrode 76c. The coil pattern 76a is electrically connected to a wiring pattern 78a by a via-hole 77a. The coil pattern 76b is electrically connected to a terminal electrode 79a by a via-hole electrode 77b.

The inductance L2 has a similar configuration, and coil patterns 80a and 80b of the inductance L2 are electrically connected by a via-hole electrode 80c. The coil pattern 80a is connected to a wiring pattern 78b by a via-hole electrode 81a. The coil pattern 80b is electrically connected to a terminal electrode 79b by a via-hole electrode 81b. In place of the via-hole electrodes 77b and 81b, side-surface electrodes may be used. The coil patterns may be meandering patterns.

As is clear from the filter devices 71 and 75 according to the modifications shown in FIGS. 18 and 19, at least one of the inductances L1 and L2 may be incorporated in a package in which a filter device is mounted. In this case, an operation to connect the inductance elements outside the packages 72 and 75 can be omitted, and the size of the electronic device in which the filter device is incorporated can be reduced. That is, an electronic device using the above-described filter device, e.g., a duplexer, can be reduced in size.

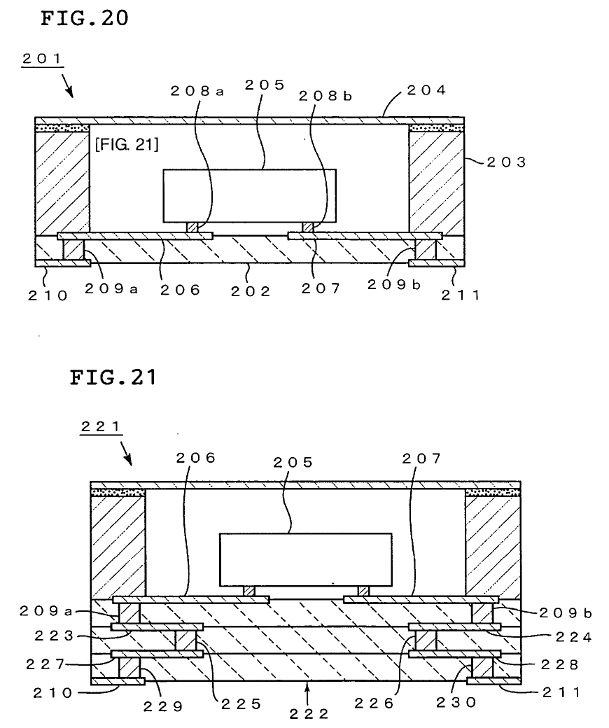

FIGS. 20 to 23 are front cross-sectional views showing modifications of the filter device structure according to a preferred embodiment of the present invention. In a filter device according to preferred embodiments of the present invention, there may be a variety of modifications of the package structure thereof.

For example, in a filter device 201 shown in FIG. 20, a package includes a substrate 202, a frame-like member 203, and a cover member 204. A SAW element 205 is mounted on the substrate 202 by the flip-chip bonding technique. That is, electrode lands 206 and 207 are provided on an upper surface of the substrate 202, and the SAW element 205 is bonded to the electrode lands 206 and 207 by metal bumps 208a and 208b. The electrode lands 206 and 207 are bonded to terminal electrodes 210 and 211 by via-hole electrodes 209a and 209b. Also in the present modification, similar to the above-described preferred embodiment, an inductance is provided, as appropriate. For example, an external inductance element may be provided.

A filter device 221 shown in FIG. 21 has a similar package structure to that of the filter device 201. However, in the filter device 221, a multilayer substrate 222 is used in place of the substrate 202. The multilayer substrate 222 includes electrode lands 206 and 207 on an upper surface thereof, and the electrode lands 206 and 207 are electrically connected to internal electrodes 223 and 224 defined in the multilayer substrate 222 for forming inductances by via-hole electrodes 209a and 209b. The internal electrodes 223 and 224 are further connected to internal electrodes 227 and 228 for forming inductances via via-hole electrodes 225 and 226. The internal electrodes 227 and 228 are connected to terminal electrodes 210 and 211 by via-hole electrodes 229 and 230. Accordingly, the inductances may be formed in the multilayer substrate 222, and a SAW element 205 may be mounted on the multilayer substrate 222 by the flip-chip bonding technique, as in the filter device 201.

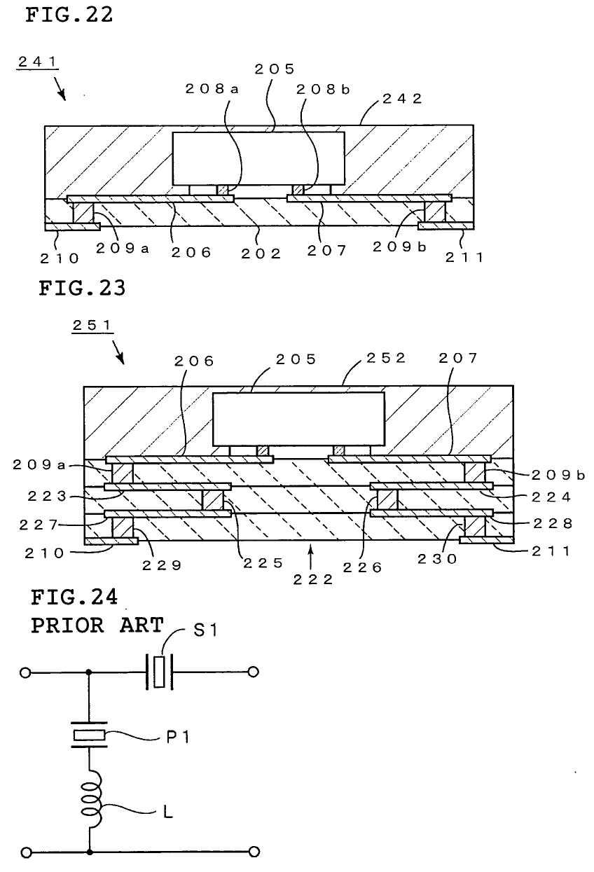

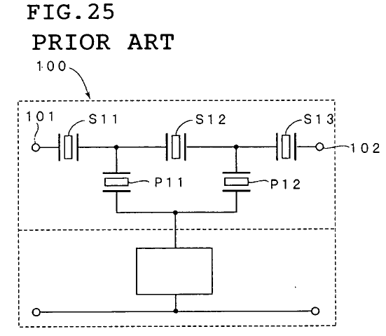

A filter device 241 shown in FIG. 22 has a similar structure to that of the filter device 201, except that an outer resin layer 242 is used in place of the frame-like member 203 and the cover member 204 shown in FIG. 20. A filter device 251 shown in FIG. 23 has a similar structure to that of the filter device 221, except that an outer resin layer 252 is used in place of the frame-like member 203 and the cover member 204. Accordingly, a package may be partially defined by the outer resin layer 242 or 252.

While the present invention has been described with respect to preferred embodiments thereof, it will be apparent to those skilled in the art that the disclosed invention may be modified in numerous ways and may assume many embodiments other than those specifically set out and described above. Accordingly, it is intended by the appended claims to cover all modifications of the invention which fall within the true spirit and scope of the invention.

1-8. (canceled)

9. A filter device for use in a communication system including a first bandpass filter having a relatively low passband frequency and a second bandpass filter having a relatively high passband frequency, the filter device defining the first bandpass filter and having a ladder circuit structure, the filter device comprising:
at least one series-arm resonator inserted in a series arm connecting an input terminal and an output terminal;
at least one parallel-arm resonator connected in at least one parallel arm connecting the series arm and a reference potential; and
an inductance connected in series with the at least one parallel-arm resonator; wherein
the inductance has an inductance value such that the frequency of a secondary resonance generated in the at least one parallel-arm resonator by inserting the inductance is within or in the vicinity of the passband of the second bandpass filter which defines a partner filter of the filter device.

10. The filter device according to claim 9, wherein each of the at least one series-arm resonator and the at least one parallel-arm resonator comprises a surface acoustic wave resonator.

11. The filter device according to claim 9, wherein each of the at least one series-arm resonator and the at least one parallel-arm resonator comprises a piezoelectric thin film resonator.

12. The filter device according to claim 11, wherein the piezoelectric thin film resonator includes a substrate having an opening portion or a recessed portion, a piezoelectric thin film disposed above the opening portion or the recessed portion, and an upper electrode and a lower electrode facing each other with the piezoelectric thin film disposed therebetween, the upper electrode being disposed on an upper surface of the piezoelectric thin film and the lower electrode being disposed on a lower surface of the piezoelectric thin film.

13. The filter device according to claim 12, further comprising a piezoelectric thin film support layer disposed between the substrate and the piezoelectric thin film so as to cover the opening portion or recessed portion of the substrate.

14. The filter device according to claim 9, further comprising a package in which the at least one series-arm resonator and the at least one parallel-arm resonator of the ladder filter are connected, wherein the inductance comprises an inductance element connected to the parallel-arm resonator outside the package.

15. The filter device according to claim 14, further comprising a mounting substrate on which the package is mounted, wherein the inductance element is embedded in the mounting substrate.

16. The filter device according to claim 9, further comprising a package in which the filter device is mounted, wherein the inductance is incorporated in the package.

17. The filter device according to claim 9, wherein each of the least one series-arm resonator and the at least one parallel-arm resonator is a one-terminal-pair surface acoustic wave resonator including an interdigital electrode and reflectors disposed on both sides of the interdigital electrode in the surface wave propagation direction.

18. The filter device according to claim 14, wherein the package includes a recessed portion, the at least one series-arm resonator and the at least one parallel-arm resonator are disposed in the recessed portion, step portions are provided on two sides of the recessed portion of the package, the step portions include electrode lands to which the at least one series-arm resonator and the at least one parallel-arm resonator are connected.

19. The filter device according to claim 14, wherein the package is made of alumina.

20. The filter device according to claim 16, wherein the inductance is a spiral inductor.

21. The filter device according to claim 9, wherein an inductance value of the inductance is in a range of about 3.5 nH to about 5 nH.

22. A filter device for use in a communication system including a first bandpass filter having a relatively low passband frequency and a second bandpass filter having a relatively high passband frequency, the filter device defining the first bandpass filter and having a ladder circuit structure, the filter device comprising:
three series-arm resonators inserted in a series arm connecting an input terminal and an output terminal;
two parallel-arm resonators connected in at least one parallel arm connecting the series arm and a reference potential; and
two inductances connected in series with the two parallel-arm resonators; wherein
the two inductances have inductance values such that the frequency of a secondary resonance generated in the two parallel-arm resonator by inserting the inductance is within or in the vicinity of the passband of the second bandpass filter which defines a partner filter of the filter device.

23. The filter device according to claim 22, wherein each of the three series-arm resonators and the two parallel-arm resonators comprises a surface acoustic wave resonator.

24. The filter device according to claim 22, wherein each of the three series-arm resonators and the two parallel-arm resonators comprises a piezoelectric thin film resonator.

25. The filter device according to claim 24, wherein the piezoelectric thin film resonator includes a substrate having an opening portion or a recessed portion, a piezoelectric thin film disposed above the opening portion or the recessed portion, and an upper electrode and a lower electrode facing each other with the piezoelectric thin film disposed therebetween, the upper electrode being disposed on an upper surface of the piezoelectric thin film and the lower electrode being disposed on a lower surface of the piezoelectric thin film.

26. The filter device according to claim 25, further comprising a piezoelectric thin film support layer disposed between the substrate and the piezoelectric thin film so as to cover the opening portion or recessed portion of the substrate.

27. The filter device according to claim 22, further comprising a package in which the three series-arm resonators and the two parallel-arm resonators of the ladder filter are connected, wherein the two inductances comprise inductance elements connected to the two parallel-arm resonators outside the package.
